(19) United States
(12) Patent Application Publication
(10) Pub. No.: US 2002/0140511 A1
(43) Pub. Date: Oct. 3, 2002

(54) Current sense automatic level control system with pre-bias

(76) Inventors: Markus Myers, Richmond (CA); Wenkai Zhong, Burnaby (CA)

Correspondence Address: Robert E. Krebs, Thelen Reid and Priest LLP, P.O. Box 640640, San Jose, CA, 95164-0640, US

(21) Appl. No.: 09/823,411

(22) Filed: Mar. 30, 2001

(51) Int. Cl. H03G 3/20

(52) U.S. Cl. 330/285

(57) ABSTRACT

A system for removing noise in a power amplifier is disclosed. The system includes a pre-bias signal generator that is operative to generate a pre-bias signal and an injection mechanism that is operative to introduce the pre-bias signal into a control signal of the power amplifier. The pre-bias signal generator and the injection mechanism may be part of a current sense automatic level control loop for the power amplifier. In this respect, the control signal may be generated in response to the current flowing through the power amplifier. The pre-bias signal may be a DC offset voltage which is operative to place the power amplifier near a conducting threshold thereof in order to reduce sideband splatter.

### BACKGROUND OF THE INVENTION

1. Field of the Invention:

The present invention generally relates to a current sense automatic level control for power amplifiers and more particularly to a pre-bias circuit for the automatic level control.

2. Status of the Prior Art:

Power amplifiers (PA's) are utilized to increase the gain of an RF signal. The power amplifier is typically found in a wireless devices such as a cellular phone. The power amplifier is controlled via a control voltage input which is derived by sensing the current flowing into the power amplifier. More specifically, a current sensor determines the current (i.e., power consumption) of the power amplifier and generates a corresponding current signal. Next, a current to voltage converter produces a voltage corresponding to the sensed current. The voltage from the current to voltage converter is directed to an input of an integrator/comparator & ramp control that generates the control voltage for the power amplifier. In this regard, the current sensor, current to voltage converter, ramp control and power amplifier define an automatic level control (ALC) loop that can control the level of the power amplifier.

Due to the characteristics of the power amplifier, there is an inherent delay in the ALC which causes the loop to be under-damped. Specifically, there is a 100 μsec delay in the ALC which leads to a large amount of sideband splatter by the power amplifier. Accordingly, the power amplifier is not at a conducting threshold due to the delay, thereby generating loop instability and sideband splatter. Also, due to the delay, the PA will be turned on much slower. Depending on the PA and its gate capacitance, transmitter turn on time (TTO) is usually a problem in design, and TTO specification is mandatory in many communication standards, such as CDPD and CDMA.

The present invention addresses the above-mentioned deficiencies in the prior art automatic level control circuitry by supplying a pre-bias signal to the power amplifier. The pre-bias signal removes any delay associated with the power amplifier reaching the threshold state thereby improving loop stability and reducing sideband splatter. The pre-bias signal also pre-charges the gate of the PA, which makes it turn on much faster.

### BRIEF SUMMARY OF THE INVENTION

In accordance with the present invention, there is provided a system for removing sideband splatter of a power amplifier that is responsive to a control signal. The system includes a pre-bias signal generator operative to generate a pre-bias signal and an injection mechanism operative to introduce the pre-bias signal into the control signal. As such, the pre-bias signal places the power amplifier near its conducting threshold in order to reduce the sideband splatter.

In the preferred embodiment, the injection mechanism is an adder operative to combine the pre-bias signal to the control signal. The pre-bias signal is a DC offset signal (i.e., voltage) that can be generated by a resistor divider network. The input of the resistor divider network may be adjusted by a digital to analog converter to vary the DC offset signal such that the pre-bias signal may compensate for variability in the manufacturing process of the power amplifier.

Typically, the control signal is generated by a controller such as an integrator/comparator and ramp control. Accordingly, the controller and the adder may be part of an automatic level control loop which controls the operation of the power amplifier. For example, the automatic level control loop may include a current sensor operative to detect the current flowing into the power amplifier. A current to voltage converter is operative to generate a corresponding voltage from the current detected by the current sensor. The voltage from the current to voltage converter is fed to the controller that is operative to generate the correct control signal. As previously mentioned, the pre-bias signal is combined with the control signal and fed to the power amplifier. In the preferred embodiment, the power amplifier is adapted to increase the gain of RF signals. As such, the introduction of the pre-bias signal into the control signal allows the power amplifier to reach a conducting threshold earlier thereby eliminating any sideband splatter.

### BRIEF DESCRIPTION OF THE DRAWING

These, as well as other features of the present invention, will become more apparent upon reference to the drawing wherein:

FIG. 1 is a block level diagram of an automatic level control circuit with noise reduction constructed in accordance with the present invention.

### DETAILED DESCRIPTION OF THE INVENTION

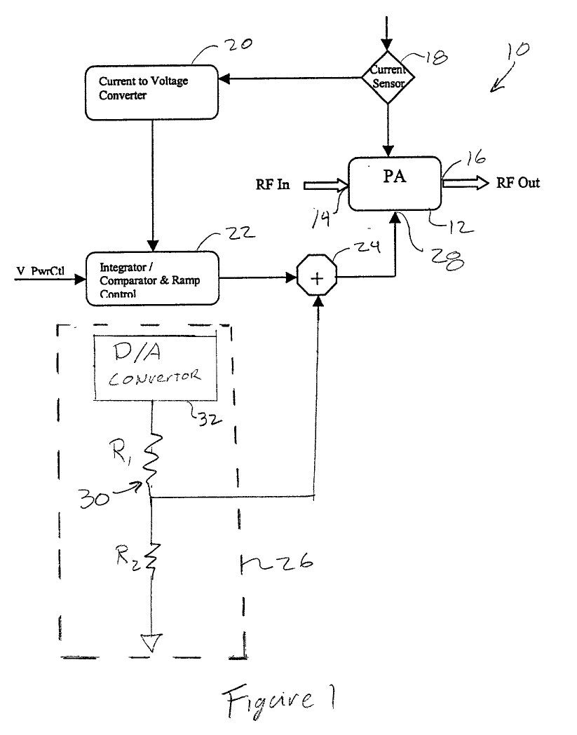

Referring now to the drawings wherein the showings are for purposes of illustrating a preferred embodiment of the present invention only, and not for purposes of limiting the same, FIG. 1 illustrates an amplification system 10 for increasing the gain of an RF signal. Specifically, the system 10 includes a power amplifier (PA) 12 that has an RF input 14 and an RF output 16. The power amplifier 12 is operative to increase the gain of an RF signal presented at the RF input 14. In this respect, the power amplifier 12 may be a component of a wireless system such as transmitter for a cellular device.

The system 10 further includes a current sensor 18 in electrical communication with the power amplifier 12. The current sensor 18 monitors the current flowing into the power amplifier 18 and is operative to generate an output corresponding to the current flowing into the power amplifier 18. The output of the current sensor 18 is fed to the input of a current to voltage converter 20. More specifically, an input of the current to voltage converter 20 receives a signal corresponding to the current flowing through the power amplifier 12 from the current sensor 18. The current to voltage converter 20 is operative to generate a voltage corresponding to the current signal from the current to voltage converter 20. The output of the current to voltage converter 20 is supplied to an input of an integrator/comparator & ramp control 22, as seen in FIG. 1. The control 22 has an input voltage V_{PwrCtl} and is operative to generate a control voltage for the power amplifier 12. The current sensor 18, the current to voltage converter 20 and the control 22 define a current sense automatic level control (ALC) loop for controlling the power amplifier 12.

In order to control under-damping of the ALC loop, the system 10 further includes an adder 24 in electrical communication with the control 22 and the power amplifier 12. Specifically, the output of the control 22 is fed to an input of the adder 24. Additionally, a pre-bias signal from a pre-bias signal generator 26 is fed as an additional input signal to the adder 24. The pre-bias signal generator 26 produces a DC offset signal (i.e., voltage) which is combined with the power amplifier control voltage signal. Accordingly, the adder 24 is operative to combine the pre-bias signal to the control voltage. The output of the adder 24 is fed to the control voltage input 28 of the power amplifier 12, as seen in FIG. 1.

The pre-bias signal 26 can be generated by a resistor divider network 30 connected to a +5V voltage source (not shown) in order to generate the DC offset voltage. Because of variability in the manufacturing of the power amplifier 12, the DC offset voltage may need to be adjusted to provide the correct amount of pre-bias. Accordingly, in order to provide variable compensation of the DC offset, the input of the resistor divider network may be connected to the output of a digital to analog converter 32 that can adjust the value of the DC offset as needed. The digital to analog converter 32 generates a precise input voltage to the resistor divider network 30. Therefore, the resistor divider network 30 can generate an exact voltage as the pre-bias signal. As such, exact calibration and adjustment of the pre-bias signal across the operating bandwidth of the power amplifier 12 is possible.

By providing the signal (i.e., DC offset), the power amplifier 12 is maintained near its conducting threshold by precharging the gate of the power amplifier 12. Accordingly, any delay in the ALC which causes the loop to be under-damped can be removed. Specifically, the 100 μsec delay associated with the power amplifier reaching the conducting threshold state is thereby removed allowing the ramp control 22 to control the ramp-up of the power amplifier 12. As such sideband splatter is reduced and stability of the ALC loop is improved.

Additional modifications and improvements of the present invention may also be apparent to those of ordinary skill in the art. Thus, the particular combination of parts described and illustrated herein is intended to represent only certain embodiments of the present invention, and is not intended to serve as limitations of alternative devices within the spirit and scope of the invention.

1. A system for removing sideband splatter of a power amplifier, the system having an automatic level control operative to generate a control signal for the power amplifier, the system comprising:
a pre-bias signal generator operative to generate a pre-bias signal; and
an injection mechanism, the injection mechanism operative to introduce the pre-bias signal into the control signal of the power amplifier;
wherein the pre-bias signal places the power amplifier near a conducting threshold in order to reduce sideband splatter.

2. The system of claim 1 wherein the injection mechanism is an adder in electrical communication with the control signal, the adder being operative to add the pre-bias signal to the control signal.

3. The system of claim 2 wherein the pre-bias generator is operative to generate a pre-bias signal that is a DC offset voltage.

4. The system of claim 3 wherein the pre-bias generator is a resistor divider network.

5. The system of claim 4 further comprising a digital to analog converter in electrical communication with the resistor divider network and operative to adjust the pre-bias signal.

6. The system of claim 1 further comprising a controller to generate the control signal for the power amplifier.

7. The system of claim 6 wherein the injection mechanism is in electrical communication with the controller in order to introduce the pre-bias signal into the control signal.

8. The system of claim 7 wherein the injection mechanism is an adder operative to add the pre-bias signal to the control signal.

9. The system of claim 8 wherein the pre-bias signal generator is operative to generate a DC offset voltage that is the pre-bias signal.

10. The system of claim 9 wherein the controller is an integrator/comparator and ramp controller.

11. An automatic level control for a power amplifier (PA), the automatic level control comprising:
a current sensor in electrical communication with the power amplifier, the current sensor being operative to determine the current of the power amplifier;
a current to voltage converter in electrical communication with the current sensor, the current to voltage converter being operative to generate a voltage corresponding to the current of the power amplifier;
a controller in electrical communication with the current to voltage converter and the power amplifier, the controller being operative to generate a control signal for the power amplifier; and
an adder in electrical communication with the controller and the power amplifier, the adder being operative to introduce a pre-bias signal for the power amplifier in order to energize the power amplifier near the conducting threshold thereof.

12. The automatic level control of claim 11 wherein the controller is operative to control a power amplifier for RF signals.

13. The automatic level control of claim 11 wherein the pre-bias signal is a DC offset voltage.

14. The automatic level control of claim 11 further comprising a resistor divider network to generate the pre-bias signal.

15. The automatic level control of claim 14 further comprising a digital to analog converter operative to adjust the input voltage to the resistor divider network and vary the voltage of the pre-bias signal.

16. The automatic level control of claim 11 wherein the controller is an integrator/comparator and ramp controller.

17. A method of reducing noise in a power amplifier comprising the step of introducing a pre-bias signal into a control signal of the power amplifier such that the power amplifier is placed near a conducting threshold thereby reducing sideband splatter.

18. The method of claim 17 wherein the pre-bias signal is added to the control signal via an adder.

19. The method of claim 17 wherein the control signal is generated via an automatic control loop.

20. The method of claim 17 further comprising the step of generating a pre-bias signal that is a DC offset signal.

21. The method of claim 20 wherein the pre-bias signal is generated from a resistor divider network.

22. The method of claim 21 wherein the pre-bias signal is adjusted by varying an input voltage to the resistor divider network.

23. The method of claim 22 wherein the input voltage of the resistor divider network is adjusted via a digital to analog converter in electrical communication with the input voltage of the resistor divider network.

24. A method of reducing noise in a power amplifier, the method comprising the steps of:
a) determining the current flowing into the power amplifier;
b) converting the current flowing into the power amplifier to a corresponding control voltage;
c) generating a control signal for the power amplifier from the control voltage;
d) adding a pre-bias signal to the control signal; and
e) inputting the control signal with the pre-bias signal to the power amplifier in order to control the operation of the power amplifier, the pre-bias signal maintaining the power amplifier near a conducting threshold thereof in order to reduce noise.

25. The method of claim 24 wherein step (a) comprises determining the current flowing into the power amplifier with a current sensor.

26. The method of claim 25 wherein step (b) comprises converting the current flowing into the power amplifier with a current to voltage converter.

27. The method of claim 26 wherein step (d) comprises adding the pre-bias signal with an adder.

28. The method of claim 24 further comprising the step of generating the pre-bias signal prior to step (c).

29. The method of claim 28 wherein the step of generating the pre-bias signal comprises generating a DC offset voltage.

30. The method of claim 29 wherein the DC offset voltage is generated with a resistor divider network.

31. The method of claim 30 further comprising the step of adjusting an input voltage of the resistor divider network in order to vary the DC offset voltage.

32. The method of claim 31 wherein the input voltage of the resistor divider network is adjusted via a digital to analog converter.
